(19) United States
(12) Patent Application Publication
(10) Pub. No.: US 2012/0135590 A1
(43) Pub. Date: May 31, 2012

(54) SILICON REMOVAL FROM SURFACES AND METHOD OF FORMING HIGH K METAL GATE STRUCTURES USING SAME

(75) Inventors: Bryan C. Hendrix, Danbury, CT (US); Emanuel I. Cooper, Scarsdale, NY (US)

(73) Assignee: ADVANCED TECHNOLOGY MATERIALS, INC., Danbury, CT (US)

(21) Appl. No.: 13/306,616

(22) Filed: Nov. 29, 2011

Related U.S. Application Data
(60) Provisional application No. 61/418,405, filed on Nov. 30, 2010.

(51) Int. Cl. H01L 21/28

(52) U.S. Cl. 438/585; 257/E21.19

(57) ABSTRACT

A method of fabricating a semiconductor device, comprising carrying out a gate last process including forming a dummy gate of polysilicon, and thereafter removing the dummy gate for replacement by a metal gate, wherein the dummy gate is removed by XeF₂ etch removal.

### CROSS-REFERENCE TO RELATED APPLICATION

The benefit of priority of U.S. Provisional Patent Application No. 61/418,405 filed Nov. 30, 2010 in the names of Bryan C. Hendrix and Emanuel I. Cooper for “SILICON REMOVAL FROM SURFACES AND METHOD OF FORMING HIGH K METAL GATE STRUCTURES USING SAME” is hereby claimed under the provisions of 35 USC 119.

### FIELD

The present disclosure relates to semiconductor device fabrication methods, and more particularly to methods for the integration of metal gates in semiconductor devices, such as metal gate transistors.

### RELATED ART

In the manufacture of semiconductor devices, the demand for smaller device features and increased performance has resulted in design changes that necessitate new methods of fabrication.

Semiconductor fabrication generally involves a multiple-step sequence of photographic and chemical processing steps during which circuits are progressively created on a wafer or other substrate, typically made of relatively pure semiconducting material such as silicon. The various steps used in semiconductor manufacturing include deposition, removal, patterning, and modification. Deposition can include sputtering, chemical vapor deposition, atomic layer deposition, and other processes that deposit and grow material on a wafer. Removal processes include wet etching, dry etching, ion milling, volatilization, and other techniques that result in material being removed from the substrate. Patterning entails processes that shape or alter the existing shape of the deposited materials, and modification includes various processes to modify the electrical properties of the wafer, such as annealing to activate implanted dopant species.

Conventional semiconductor devices can include large numbers of metal oxide semiconductor field effect transistors (“MOSFET”), each comprising at least one source, drain and gate region. Complementary metal-oxide-semiconductors (“CMOS”) use complementary and symmetrical pairs of p-type and n-type MOSFETs, allowing for a higher density of logic functions on a chip.

The gate region of MOS or CMOS transistors is generally made of a metal gate material (e.g., polysilicon) placed over or on top of an oxide insulator/dielectric (e.g., SiO₂), which in turn overlies or is on top of a semiconductor material, a combination that is commonly referred to as a “gate stack.” Despite the reference to “metal” in metal gate and metal oxide semiconductors, polysilicon (polycrystalline silicon) is the most common gate material in conventional gate fabrication. Polysilicon has been a preferred material in the fabrication of gate electrodes due to the ease with which it is deposited, its tolerance to extremely high temperatures (in excess of 900-1000° C.) in subsequent manufacturing steps (e.g., annealing), and its ability to form self-aligned gates. Gate fabrication with metals suffers from many of the problems that polysilicon avoids.

The gate dielectric of choice in the prior art has long been silicon dioxide. As transistors have decreased in size, the thickness of the silicon dioxide dielectric has also been scaled down in order to improve gate capacitance, thereby enhancing current and device performance. The reduction in silicon dioxide gate thickness below approximately 2 nm has resulted in drastically increased leakage currents due to tunneling, which leads to unwieldy power consumption and reduced device reliability. The solution has been to replace the silicon dioxide gate dielectric with a high-κ (high dielectric constant) material (e.g., hafnium silicate, zirconium silicate, hafnium dioxide, or zirconium dioxide) that will allow an increased gate capacitance without the concomitant leakage effects. Replacing the silicon dioxide gate dielectric with another material, however, has been found to complicate the manufacturing process.

Due to compatibility issues between standard polysilicon gates and high-κ gate dielectrics, the high-κ gate dielectrics are more advantageously paired with metal gate electrodes (e.g., TiN for p-type gates; TiAlN for n-type gates). Such compatibility issues include the prevention of transistors from being switched properly at low threshold voltages (“Fermi pinning”), and the resulting defects in bandgap that prevent gate voltage swing (resulting in a high Vt, or increased delay time). In addition, metal gates are not susceptible to the depletion effects that occur when polysilicon gates are employed. As the effective physical gate dielectric thickness decreases, the polysilicon depletion contributes proportionally to the overall gate dielectric thickness in the semiconductor device. As a result, it is desirable to eliminate polysilicon depletion in order to scale gate oxide thickness by using a metal gate in place of a polysilicon gate. Metallic gates also enable an increase in speed of transistor operation to be achieved at smaller scales.

Metal gates, however, pose a number of additional challenges in semiconductor fabrication, including a tendency to disperse into silicon and/or migrate towards midgap work functions during high-temperature thermal annealing. It is important for metal incorporated into semiconductor wafers not to be exposed to high temperatures. One proposed solution is utilization of a gate-last process strategy (also known as “replacement gate,” “dummy poly-gate,” or “cold flow process”), in which the metal electrode is deposited after the high temperature activation anneal(s). In the gate-last process, a polysilicon dummy gate is patterned in the traditional self-aligned process. Once the remaining processing steps are completed, the dummy gate is removed to expose a recess, and a metal is deposited in its place. The recess may be filled with a metal using PVD (“physical vapor deposition”), CVD (“chemical vapor deposition”), or ALD (“atomic Layer deposition”). CVD and ALD may use an organometallic or halide precursor, and a reducing atmosphere. The removal of the dummy gate by traditional methods, however, poses difficulties that are unique to the gate-last process.

Traditional semiconductor etching methods, wet and dry, are not selective and will attack not only the sacrificial polysilicon dummy gate, but other exposed films as well. Strong bases will attack silicon dioxide, oxidants will attack TiN, and HF-containing (or generating) reagents will attack all layers. Wet etching, while a simple and relatively inexpensive technology, results in undercutting of an extent that is generally equal to the depth of etch. Dry etching entails a cost per wafer that is typically 1-2 orders of magnitude higher than the cost of wet etching.

Among p-type and n-type polysilicon transistors, p-doped polysilicon is much harder to etch. Ammonium hydroxide etching is commonly used for removal of n-type polysilicon, but other approaches are utilized for p-type silicon removal, which require additional processing steps. Removal of p-type polysilicon is conventionally carried out by wet etching using tetramethylammonium hydroxide.

Without the ability to selectively etch (i.e., etch a desired or target material while minimizing or otherwise reducing damage to other exposed films) the dummy-poly gate, alternative methods have been employed that include depositing a protective layer over the gate dielectric. In the fabrication of a p-type transistor, a protective layer of titanium nitride may be deposited after the dielectric layer (e.g., formed of a material such as HfO₂) is formed, in order to protect the dielectric layer in the subsequent dummy polysilicon etch. In the fabrication of n-type transistors, a protective layer of titanium aluminum nitride may be correspondingly deposited on the dielectric layer. In such deposition techniques, the protective layer is commonly referred to a first work function layer or top interface layer (“TIL”). Thicker layers of such metals are deposited in their respective n-type and p-type transistors after removing the sacrificial polysilicon. Insertion of even a thin TIL comprising metal prior to the annealing step nonetheless creates the same issues regarding the presence of metal during annealing, such as contamination of surrounding layers with the metal. Such problems are further exacerbated in the fabrication of CMOS devices having both p-type and n-type transistors, such each of such transistor structures requires a dummy gate to be separately removed and filled using different reagents and/or processes.

In consequence, the art continues to seek improvements in methods of fabricating semiconductor devices involving dummy poly-gate techniques, which are applicable to both n-doped and p-doped polysilicon devices.

### SUMMARY

The present disclosure relates to integration of metal gate transistors in semiconductor devices and to methods of fabricating semiconductor devices comprising metal gate transistors.

In one aspect, the disclosure relates to a method of fabricating a semiconductor device, comprising carrying out a gate last process including forming a dummy gate of polysilicon, and thereafter removing the dummy gate for replacement by a metal gate, wherein the dummy gate is removed by XeF₂ etch removal thereof.

In another aspect, the disclosure relates to a method of integrating a metal gate transistor in a semiconductor device, comprising: providing a first semiconductor wafer; depositing over the first semiconductor wafer a first layer comprising a first dielectric material; depositing over the first layer a second layer comprising polysilicon; forming a first recess by selectively etching at least part of the second layer with xenon difluoride (XeF₂); and depositing a first metal-containing material in at least a portion of the first recess.

In still another aspect, the disclosure relates to a method of fabricating a semiconductor device, comprising: providing a substrate having a first gate transistor comprising an n-type gate material over a first dielectric material and a second gate transistor comprising a p-type gate material over a second dielectric material; selectively removing at least part of the n-type gate material with XeF₂ to form a first recess in the first gate transistor; depositing an n-type metal gate material in the first recess; selectively removing at least part of the p-type gate material with XeF₂ to form a second recess in the second gate transistor; and depositing a p-type metal gate material in the second recess.

Other aspects, features and embodiments of the disclosure will be more fully apparent from the ensuing description and appended claims.

### BRIEF DESCRIPTION OF THE DRAWINGS

FIG. 1 is a flowchart depicting the fabrication of a semiconductor device incorporating a metal gate according to one embodiment of the present disclosure.

### DETAILED DESCRIPTION

The present disclosure relates to semiconductor device fabrication, and more specifically to methods for the integration of metal gate transistors and methods of fabricating semiconductor devices incorporating metal gate transistors.

In one aspect, the disclosure relates to a method of fabricating a semiconductor device, comprising carrying out a gate last process including forming a dummy gate of polysilicon, and thereafter removing the dummy gate for replacement by a metal gate, wherein the dummy gate is removed by XeF₂ etch removal thereof.

As used herein, the terms “high-κ material” and “high-κ dielectric” refer to dielectric materials having a dielectric constant (“κ”) greater than about 8, and preferably greater than 10. High-κ dielectric materials include, but are not limited to, materials such as hafnium silicate, zirconium silicate, hafnium dioxide, zirconium dioxide, hafnium silicon oxynitride, and hafnium silicon nitride. In various embodiments of the present disclosure, a high-κ dielectric material functions as an electrical insulation medium between conductive areas of a semiconductor transistor.

As used herein, the terms “replacement gate,” “dummy poly-gate,” and “dummy gate” refer to dummy polysilicon or the polysilicon gate replaced in a gate-last process (“cold flow process”) with a metal electrode, e.g., in a process sequence in which the metal electrode is deposited after high temperature activation annealing. The dummy polysilicon may be doped to provide p-doped and/or n-doped gate material, so that the resulting p-doped and/or n-doped material may be selectively removed. A p-doped material may for example be doped with a dopant species from Group IIIA of the Periodic Table, such as boron or aluminum. An n-doped material may for example be doped with a dopant species from Group IV (silicon, germanium, or tin) or Group V (phosphorus, arsenic, or antimony) of the Periodic Table. A material comprising polysilicon may be doped with any of the above p-type or n-type dopants, including any combinations thereof, and/or any other suitable dopant species.

As used herein, the terms “gate metal” and “work function metal” refer to any metal substituted for the dummy polysilicon gate of a semiconductor transistor. Such metals can be specific to either p-type gates or n-type gates. P-type metals can include, but are not limited to, Ru (ruthenium), Pd (palladium), Pt (platinum), Co (cobalt), Ni (nickel), TiAIN (titanium aluminum nitride), and WCN (tungsten carbon nitride). N-type metals can include, but are not limited to, Hf (hafnium), Zr (zirconium), Ti (titanium), Ta (tantalum), and Al (aluminum).

As used herein, the terms “selectively removing” and “selectively etching” refer to the removal by etching of a specific material while achieving reduced removal of material from other exposed films. Selective etching of polysilicon with xenon difluoride can be carried out for removal of polysilicon from a substrate while achieving reduced removal of a dielectric on the same substrate, so that the damage to the dielectric is minimized or otherwise sufficiently low so that the dielectric is “substantially preserved.” The dielectric is substantially preserved when at least 50%, and more preferably at least 60%, 70%, 80% or 90%, of the dielectric present prior to the selective etching remains incorporated in the semiconductor wafer after such etching.

As used herein, the term “on” in specifying the relationship of a material to a specific layer in a semiconductor device or precursor structure therefor, denotes such material as being in contact with the surface of the specific layer, while the term “over” in specifying the relationship of a material to a specific layer in a semiconductor device or precursor structure therefor, denotes such material as being either in contact with the surface of the specific layer or above the surface of the specific layer (i.e., with intervening material or layers separating them).

As used herein, the term “film” refers to a layer of deposited material having a thickness below 1000 micrometers, e.g., from such value down to atomic monolayer thickness values. In various embodiments, film thicknesses of deposited material layers in the practice of the invention may for example be below 100, 10, or 1 micrometers, or in various thin film regimes below 200, 100, or 50 nanometers, depending on the specific application involved. As used herein, the term “thin film” means a layer of a material having a thickness below 1 micrometer.

It is noted that as used herein and in the appended claims, the singular forms “a”, “and”, and “the” include plural referents unless the context clearly dictates otherwise.

The disclosure, as variously set out herein in respect of features, aspects and embodiments thereof, may in particular implementations be constituted as comprising, consisting, or consisting essentially of, some or all of such features, aspects and embodiments, as well as elements and components thereof being aggregated to constitute various further implementations of the disclosure. The disclosure contemplates such features, aspects and embodiments in various permutations and combinations, as being within the scope of the disclosure. The disclosed subject matter may therefore be specified as comprising, consisting or consisting essentially of, any of such combinations and permutations of these specific features, aspects and embodiments, or a selected one or ones thereof.

The advantages and features of the disclosure are further illustrated with reference to the following examples, which are not to be construed as in any way limiting the scope of the disclosure but rather as illustrative of one or more embodiments of the invention in specific applications thereof.

In one embodiment, a method of integrating a metal gate transistor in a semiconductor device is provided, comprising the steps of: providing a first semiconductor wafer; depositing over the first semiconductor wafer a first layer comprising a first dielectric material; depositing over the first layer a second layer comprising polysilicon; forming a first recess by selectively etching at least part of the second layer with XeF₂, wherein the first layer is substantially preserved; and depositing a first metal material in at least a portion of the first recess.

The polysilicon layers may be doped with one or more p-type or n-type materials, e.g., to allow each to be distinguished during the dummy gate removal step. Doping may be accomplished with any methods, processes and/or techniques known in the art. In one embodiment, a method of removing the dummy poly-gate incorporates a dry vapor phase isotropic etch with xenon difluoride.

The disclosure in various embodiments contemplates the application of a XeF₂ etch to remove a dummy gate in a gate last process. In such application, the dummy gate is advantageously formed of polysilicon, but the disclosure contemplates the use of a XeF₂ etch to remove a dummy gate in a gate last process, in which other dummy gate material comprises other material that is susceptible to selective removal with XeF₂, e.g., silicon germanide (SiGe) or other suitable gate material.

It has been discovered that while XeF₂ is highly selective to silicon, it will not damage many other exposed films commonly present with the dummy gate on the semiconductor device structure, including, but not limited to, SiO₂, Si₃N₄, and TiN. It also has been discovered that XeF₂ can be utilized on both n-doped and p-doped polysilicon, which is an important advantage since p-doped polysilicon is substantially harder to etch than n-doped polysilicon and generally requires a different process and/or etchant. It has also been discovered that while the removal rate for silicon and dopants is high, the etch rate for commonly used dielectrics such as those illustratively identified above is very low, and near zero in most instances. Protection of either the p-doped or n-doped polysilicon will be necessary if both are present and it is desired to remove each dummy gate separately, e.g., so that different p-type and n-type metals may be introduced into each respective recess formed by the XeF₂ etch of the corresponding p-doped or n-doped polysilicon. Such protection may include depositing a suitable XeF₂-resistant material, such as an oxide, a nitride, or a photoresist over one of the respective p-doped and n-doped polysilicon materials, to protect it while the other of the respective p-doped and n-doped polysilicon materials is being removed by XeF₂ etch.

Since XeF₂ will not etch SiO₂, all native oxides will generally need to be removed from the polysilicon that is intended to be etched. So long as there is a dielectric such as SiO₂, Si3N₄, or TiN (of at least 2 Å thickness) below the dummy poly-gate, XeF₂ will generally provide a very clean stop on the dielectric.

The substitution of metal for the polysilicon dummy gate provides many of the benefits as outlined herein, but will preferably be substituted for the sacrificial poly-gate after high-temperature annealing (comprising one or more anneal steps) to avoid contamination of the wafer with the metal. This “gate last” process further ensures the integrity of the metal gate as incorporated into the semiconductor device transistor. One particular benefit is the incorporation of metal gates that are compatible with high-κ dielectric materials. While the present disclosure contemplates the integration of a metal gate on a SiO₂ dielectric in various embodiments thereof, other high-κ dielectric materials in structures requiring metal gates provide additional embodiments and applications for the method of the present disclosure.

In one embodiment of the present disclosure, a semiconductor device is fabricated by a method comprising the steps of: providing a substrate including a first gate transistor comprising an n-type gate material over a first dielectric material and a second gate transistor comprising a p-type gate material over a second dielectric material; selectively removing at least a portion of the n-type gate material with XeF₂ to form a first recess in the first gate transistor; depositing an n-type metal gate material in the first recess; selectively removing at least a portion of the p-type gate material with XeF₂ to form a second recess in the second gate transistor; and depositing a p-type metal gate material in the second recess.

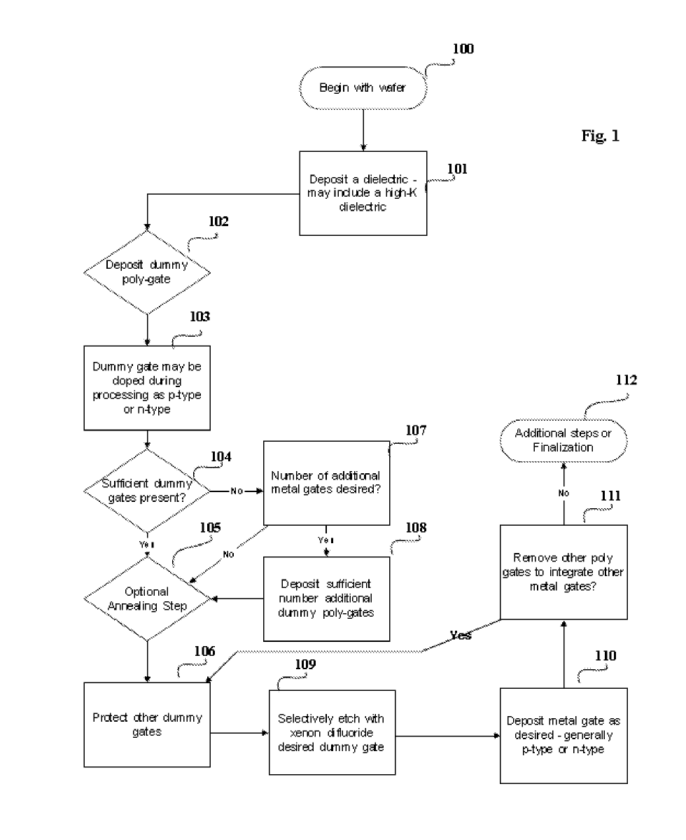

One illustrative method of the present disclosure is depicted in the flowchart in FIG. 1. The method is initiated with a wafer or substrate 100 that may be pre-fabricated with one or more layers, processed regions, etc., prior to its processing by the illustrative method. A dielectric is deposited (step 101). The dielectric material can be SiO₂ or other high-κ dielectric material. A dummy polysilicon gate is then deposited over the dielectric (step 102). The dummy gate may be doped (step 103) with one of a p-type and n-type material during the process, or prior to deposition step 102. A determination is made as to whether sufficient dummy poly-gates are present on the wafer (step 104). The deposition of dummy poly-gates in step 102 may be repeated for multiple p-doped and/or n-doped poly-gates. If sufficient gates are present, then an optional annealing (step 105) can be carried out. If sufficient gates are not present, then a determination is made of the number of additional metal gates to be provided (step 107). If additional metal gates are necessary, then additional dummy poly-gates are deposited (step 108), followed by the optional annealing (step 105). If additional metal gates are not required, then the optional annealing (step 105) can be carried out.

Following the optional annealing (step 105), the metal gates are introduced. The first step in the integration of metal gates is the protection of any other dummy gates not intended to be replaced at this stage (step 106). Such protection incorporates a XeF₂-resistant material such as an oxide, a nitride, or a photoresist over the poly-gate to be protected. The selective etching of the intended target dummy gates then is carried out with a XeF₂ etch (step 109). In consequence of its selectivity, the XeF₂ does not etch the underlying dielectric previously deposited in step 101. Following the xenon difluoride etch (step 109), a gate metal or work function metal is deposited (step 110) in the recess formed by the xenon difluoride etch. This step is followed by a determination of whether to integrate additional metal gates (step 111), e.g., in a circumstance in which a p-type or n-type gate is integrated, and the alternative n-type or p-type gate is subsequently separately integrated. If the determination in step 111 is affirmative, then the step of protecting other dummy gates 106 is carried out, as applicable. If the determination 111 is negative, then any remaining processing operations (step 112) can be carried out to complete the fabrication of the semiconductor product.

While the disclosure has been has been set out herein in reference to specific aspects, features and illustrative embodiments, it will be appreciated that the scope of the disclosure is not thus limited, but rather extends to and encompasses numerous other variations, modifications and alternative embodiments, as will suggest themselves to those of ordinary skill in the field of the disclosure. Correspondingly, the disclosure is intended to be broadly construed and interpreted, as including all such variations, modifications and alternative embodiments, within its spirit and scope.

What is claimed is:

1. A method of semiconductor fabrication, comprising:
providing a first semiconductor wafer;
depositing over the first semiconductor wafer a first layer comprising a first dielectric material;
depositing over the first layer a second layer comprising polysilicon;
forming a first recess by selectively etching at least part of the second layer with XeF₂; and
depositing a first metal material in at least a portion of the first recess.

2. The method of claim 1, wherein the second layer comprises at least one of: (i) n-doped polysilicon, and (ii) p-doped polysilicon.

3. The method of claim 2, wherein the n-doped polysilicon is doped with a material selected from the group consisting of silicon, germanium, tin, phosphorus, arsenic, and antimony.

4. The method of claim 2, wherein the p-doped polysilicon is doped with a material selected from the group consisting of boron and aluminum.

5. The method of claim 1, wherein the first metal material comprises at least one of: (i) n-type metal, and (ii) p-type metal.

6. The method of claim 5, wherein the n-type metal is selected from the group consisting of hafnium, zirconium, titanium, tantalum, and aluminum.

7. The method of claim 5, wherein the p-type metal is selected from the group consisting of ruthenium, palladium, platinum, cobalt, nickel, titanium and tungsten.

8. The method of claim 1, further comprising depositing an XeF₂-resistant material prior to forming said first recess.

9. The method of claim 8, wherein the XeF₂-resistant material is selected from the group consisting of oxides, nitrides, and photoresists.

10. The method of claim 1, wherein the dielectric material comprises a material selected from the group consisting of silicon dioxide, hafnium silicate, zirconium silicate, hafnium dioxide, and zirconium dioxide.

11. A method of fabricating a semiconductor device, comprising:
providing a substrate having a first gate transistor comprising an n-type gate material over a first dielectric material and a second gate transistor comprising a p-type gate material over a second dielectric material;
selectively removing at least part of the n-type gate material with XeF₂ to form a first recess in the first gate transistor;
depositing an n-type metal gate material in the first recess;
selectively removing at least part of the p-type gate material with XeF₂ to form a second recess in the second gate transistor; and
depositing a p-type metal gate material in the second recess.

12. The method of claim 11, wherein the n-type gate material comprises polysilicon doped with a material selected from the group consisting of silicon, germanium, tin, phosphorus, arsenic, and antimony.

13. The method of claim 11, wherein the p-type gate material comprises polysilicon doped with a material selected from the group consisting of boron and aluminum.

14. The method of claim 11, wherein the n-type metal gate material is selected from the group consisting of hafnium, zirconium, titanium, tantalum, and aluminum.

15. The method of claim 11, wherein the p-type metal gate material is selected from the group consisting of ruthenium, palladium, platinum, cobalt, nickel, titanium and tungsten.

16. The method of claim 11, further comprising removing oxide from at least one of the gate materials prior to selectively removing at least part of such gate material.

17. The method of claim 11, further comprising depositing XeF₂-resistant material on one of the gate materials prior to selectively removing at least part of the other gate material.

18. The method of claim 17, wherein the XeF₂-resistant material is selected from the group consisting of oxides, nitrides, and photoresists.

19. The method of claim 11, wherein at least one of the first and second dielectric material comprises a material selected from the group consisting of silicon dioxide, hafnium silicate, zirconium silicate, hafnium dioxide, and zirconium dioxide.

20. A method of fabricating a semiconductor device, comprising carrying out a gate last process including forming a dummy gate of polysilicon, and thereafter removing the dummy gate for replacement by a metal gate, wherein the dummy gate is removed by XeF₂ etch removal.
